(19) United States
(12) Patent Application Publication
(10) Pub. No.: US 2026/0360444 A1
(43) Pub. Date: Nov. 12, 2026

(54) METHODS AND SYSTEMS TO PERFORM LOW POWER GANGED RESET READ OPERATIONS

(71) Applicant: Micron Technology, Inc., Boise, ID (US)

(72) Inventors: Go Shikata, San Jose, CA (US); Yuxing Liu, San Jose, CA (US); Joshua C. Garrison, Folsom, CA (US); Lei Lin, Fremont, CA (US)

(73) Assignee: Micron Technology, Inc., Boise, ID (US)

(21) Appl. No.: 19/653,994

(22) Filed: Apr. 21, 2026

Related U.S. Application Data
(60) Provisional application No. 63/802,488, filed on May 8, 2025.

(51) Int. Cl. G11C 16/26; G11C 16/04; G11C 16/08

(52) U.S. Cl. CPC G11C 16/26; G11C 16/0483; G11C 16/08

(57) ABSTRACT

Methods, systems, and devices for techniques for low power ganged reset read operations. A memory device may include a global word line; word lines comprising a first subset coupled to a first group of memory cells; and a second subset coupled to a second group of memory cells; and control logic. The control logic may cause a first BLKSEL signal to be applied to the first subset to connect the first subset to the global word line for a period of time such that the first subset is charged to a pass-through voltage level. The control logic may cause, during a recovery phase of the period of time, a second BLKSEL signal to be applied to the second subset such that the second subset connects to the global word line and the first subset to cause the first subset to charge the second subset to a pre-charged voltage level.

### CROSS-REFERENCE TO RELATED APPLICATION

This patent application claims the benefit of and priority to U.S. Provisional App. No. 63/802,488 filed May 8, 2025 titled “METHODS AND SYSTEMS TO PERFORM LOW POWER GANGED RESET READ OPERATIONS,” which is incorporated in the present disclosure by reference in its entirety.

### TECHNICAL FIELD

This disclosure relates to one or more systems for memory, including techniques for performing low power ganged reset read operations.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIGS. 4A and 4B illustrates an example three-dimensional structure of a memory device in accordance with examples as disclosed herein.

FIG. 5 illustrates an example of a portion of an array of memory cells in a memory device, in accordance with examples as disclosed herein.

FIGS. 6A and 6B illustrate graphical representations of example sets of waveforms corresponding to a seamless protocol, in accordance with examples as disclosed herein.

FIG. 7 illustrates a graphical representation of example sets of waveforms corresponding to a sharing operation, in accordance with examples as disclosed herein.

FIG. 8 illustrates a graphical representation of example sets of waveforms corresponding to a ganged operation, in accordance with examples as disclosed herein.

FIG. 9 illustrates a graphical representation of operating currents of a memory device and word lines voltages captured as part of a simulation of the ganged operation and a simulation of the sharing operation, in accordance with examples as disclosed herein.

FIG. 10 illustrates flowcharts showing a method or methods that support techniques for performing low power ganged reset read in accordance with examples as disclosed herein.

### DETAILED DESCRIPTION

A memory device typically includes many memory cells. At least some memory cells of a memory device can be set or reset to a transient state by performing a reset read operation during power up or a background operation of the memory device. The memory device can perform the reset read operation to clear errors or to reset the memory cells for subsequent read operations. For example, the memory device may perform the reset read operation to reduce a bit error rate (BER).

Some memory devices may perform the reset read operation on individual memory cells or individual rows of memory cells. To perform the reset read operation, these memory devices provide a block select (BLKSEL) signal to word lines (e.g., via the string transistors corresponding to the word lines) corresponding to individual memory cells or individual rows of memory cells to couple the word lines to a global word line. These memory devices, however, may need to take a long time to perform the reset read operation due to the large number of memory cells and/or rows of memory cells in the memory device. In addition, the number of memory cells that can be reset during the power up or the background operation may be limited.

To reduce an amount of time to reset the memory cells, some memory devices may perform a ganged reset read operation (referred to herein as “ganged operation”). These memory devices include one or more groups (e.g., gang) of memory cells. These groups of memory cells can be memory blocks (generally referred to herein as “block” or “blocks”). The memory devices can also include one or more groups of multiple blocks. For example, one group of memory cells may include multiple blocks. The memory device can provide the BLKSEL signal to the word lines (e.g., the string transistors) corresponding to the block or the group of blocks to couple the word lines to the global word line. In some examples, the word lines are also referred to as local word lines. For example, these memory devices may group four blocks, eight blocks, sixteen blocks, or sixty-four blocks together for the ganged operation. These memory devices provide the BLKSEL signal to the word lines (e.g., via the string transistors corresponding to the word lines) corresponding to the grouped blocks to couple the word lines to the global word line.

During the ganged operation, the BLKSEL signal may cause the word lines corresponding to a current block or a current group of blocks to be charged (e.g., the voltages of the word lines increased from a ground level to a charged level). In addition, after the corresponding memory cells have been reset, the residual charge on the word lines may be dissipated to a circuit ground (e.g., the voltages of the word lines decreased from the charged level to the ground level). Accordingly, the residual charges on the word lines are wasted by dissipating it to the circuit ground.

Using a ganged operation, the memory devices may use less time resetting the memory cells compared to the memory devices that individually reset the memory cells or the individual rows of memory cells. In other words, during a ganged operation, these memory devices can reset more memory cells during the power up or the background operation compared to the memory devices that individually reset the memory cell or the individual rows of memory cells. However, during a ganged operation, a number of blocks or groups of blocks that can be reset during the power up or the background operation may be limited, because an amount of time to reset all the memory cells is equal to an amount of time to reset an individual block or an individual group of blocks multiplied by a number of blocks or a number of groups of blocks. In addition, these memory devices may include an increased operating current (ICC) compared to the memory devices that individually reset the memory cells or the individual rows of memory cells.

The present disclosure provides techniques for avoiding or reducing the technical difficulties described above. Some embodiments described in the present disclosure include a memory device that is configured to perform charge sharing between blocks or groups of blocks during the ganged operation in accordance with a seamless protocol.

In one example, a memory device of the present disclosure performs the ganged operation on a first block. The memory device provides the BLKSEL signal to the word lines corresponding to the first block (e.g., a first subset of word lines) to couple the first subset of word lines to the global word line and be charged. During a recovery phase of the ganged operation on the first block, the memory device causes the global word line to float. In addition, the memory device provides the BLKSEL signal to the word lines corresponding to a second block (e.g., a second subset of word lines) to couple the second subset of word lines to the first subset of word lines in accordance with a charge sharing operation. Accordingly, the first subset of word lines shares the charge stored thereon with the second subset of word lines to pre-charge the second subset of word lines. Therefore, the second subset of word lines is pre-charged when the memory device performs the ganged operation on the second block.

The memory device described in the present disclosure can reduce a ramp up time for the second block (e.g., an overall amount of time to perform the ganged operation or latency) because the second subset starts with a voltage that is above a ground voltage level. Correspondingly, the memory device can reset more memory cells during the power up or the background operation compared to the memory devices that perform the ganged operation on individual blocks or individual groups of blocks described above. In addition, the memory device described in the present disclosure may include a reduced operating current (ICC) compared to the memory devices that perform the ganged operation on individual blocks or individual groups of blocks described above by sharing the charge between the first subset of word lines and the second subset of word lines. Moreover, by charge sharing, the waste of charges on the first subset of word lines can be reduced or eliminated. Details of the techniques are described in greater detail below.

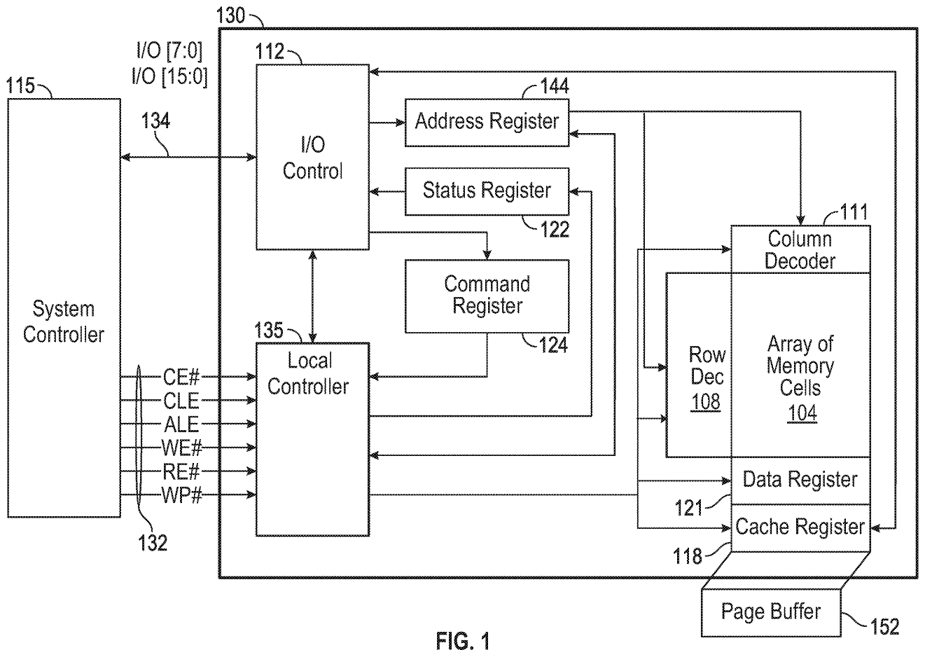

FIG. 1 is a simplified block diagram of a memory device 130 in communication with a system controller 115 of a memory system. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, which may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. The row decode circuitry 108 and the column decode circuitry 111 may simply be referred to as a row decoder 108 and a column decoder 111, respectively. A command register 124 is in communication with the I/O control circuitry 112 and a local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with the row decode circuitry 108 and the column decode circuitry 111 to control the row decode circuitry 108 and the column decode circuitry 111 according to the addresses.

In some embodiments, the local controller 135 communicates with the external system controller 115, which may be a host controller (e.g., an UFS or eMMC controller, or a CPU communicating with the local controller 135) located in a host system or a memory system controller located in a memory system. In some embodiments, the local controller 135 is disposed on the same semiconductor die as the memory array (e.g., array of memory cells 104), and a separate system controller 115 is disposed on a different die. In other examples, some portions of the memory device 130 may be disposed on a first die and other portions of memory device 130 may be disposed on a second die different from the first die. For instance, the first die may include the array of memory cells 104 and its associated circuitry such as the column decoder 111 and the row decoder 108, etc. The second die may include logic circuitry, power circuitry, or other circuitry of the memory device 130. Thus, the second die may include the system controller 115, the I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, the system controller 115 and the local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

The local controller 135 is also in communication with a cache register 118 and a data register 121. In some embodiments, one or more cache registers 118 can collectively form at least a part of a cache buffer. The cache register 118 latches or buffers data, either incoming or outgoing, as directed by the local controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in the cache register 118 from the I/O control circuitry 112. During a read operation, data can be passed from the cache register 118 to the I/O control circuitry 112 for output to the system controller 115; then new data can be passed from the data register 121 to the cache register 118. In some embodiments, the cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line (e.g., bit lines 204) connected to that memory cell. A status register 122 can be in communication with the I/O control circuitry 112 and the local controller 135 to latch the status information for output to system controller 115.

As shown in FIG. 1, memory device 130 receives various control signals via the local controller 135 from the system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over the control link 132 depending upon the nature of the memory device 130. In one embodiment, the memory device 130 receives command signals (which represent commands), address signals (which represent addresses), and data signals (which represent data) from the system controller 115 over a multiplexed input/output (I/O) bus 134 and outputs data to the system controller 115 over the I/O bus 134.

For example, the commands can be received over input/output (I/O) pins [7:0] of the I/O bus 134 at the I/O control circuitry 112 and can then be written into a command register 124. The addresses can be received over input/output (I/O) pins [7:0] of the I/O bus 134 at the I/O control circuitry 112 and can then be written into the address register 144. The data can be received over input/output (I/O) pins [7:0] for an 8-bit device or input/output (I/O) pins [15:0] for a 16-bit device at the I/O control circuitry 112 and then can be written into the cache register 118. The data can be subsequently written into the registers 121 for programming the array of memory cells 104.

In an embodiment, the cache register 118 can be omitted, and the data can be written directly into the registers 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

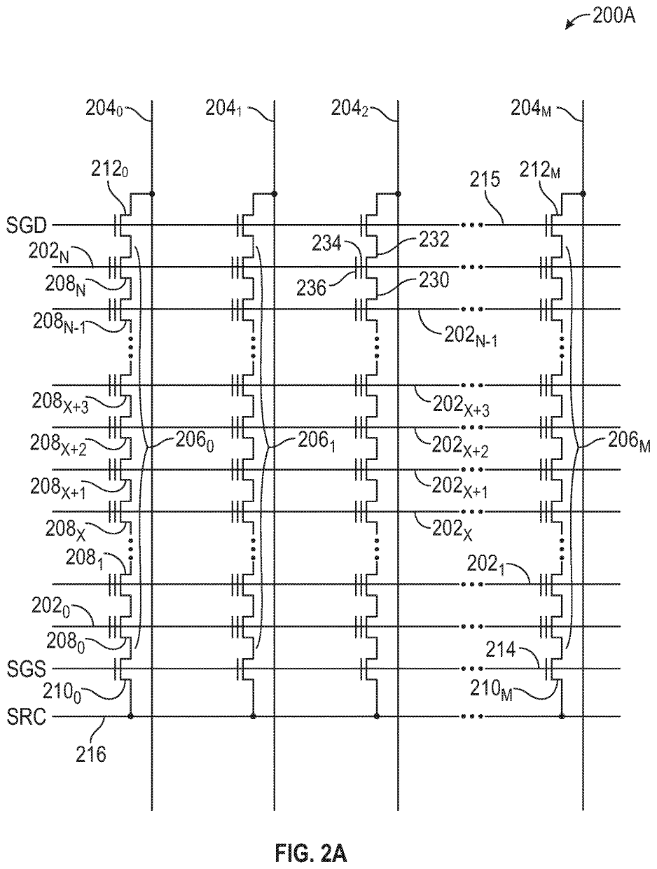

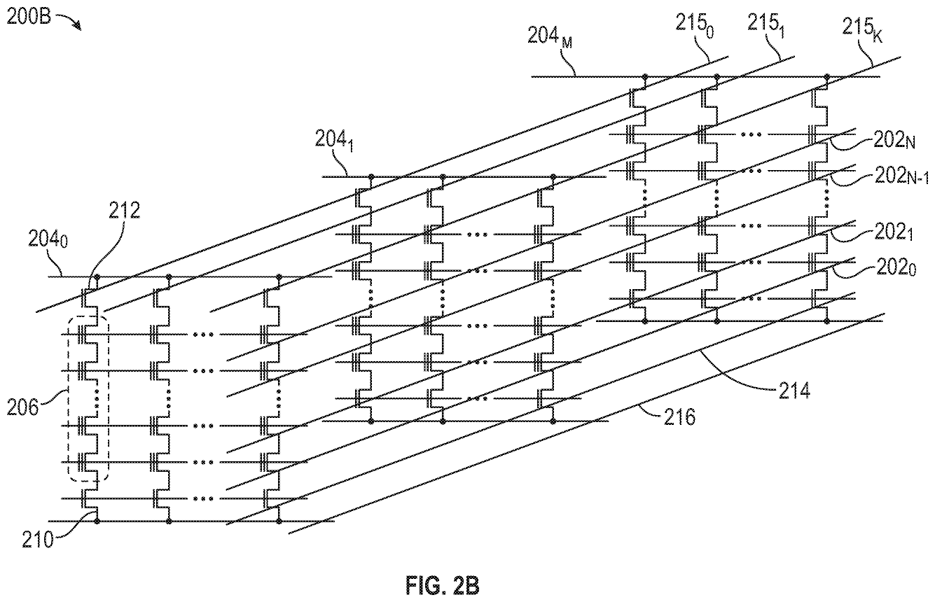

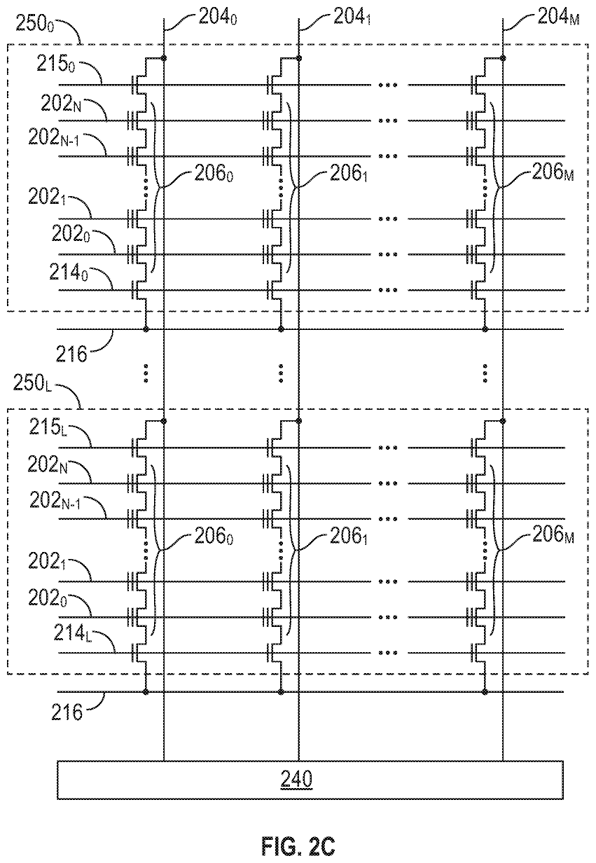

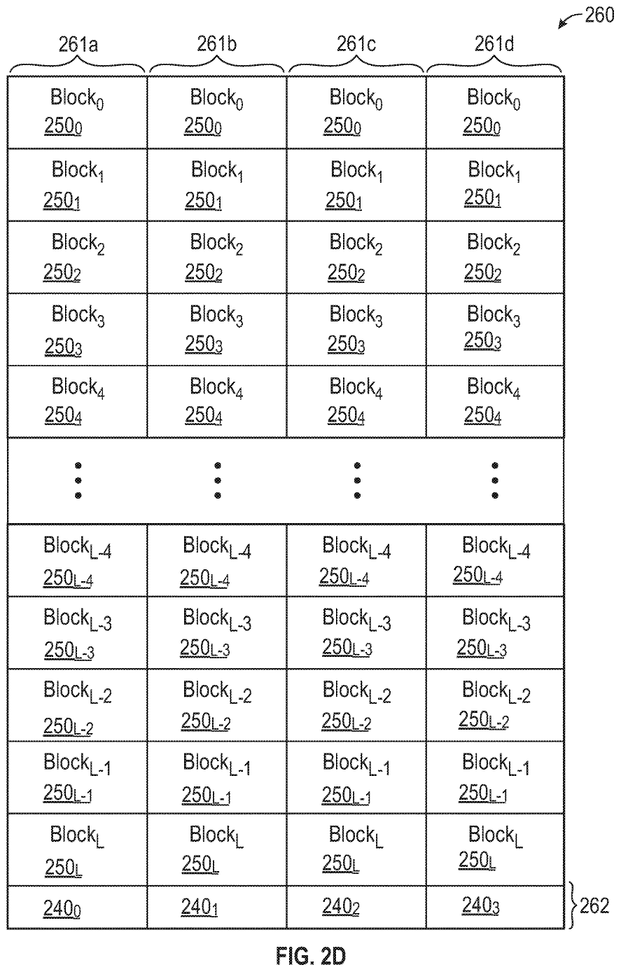

FIG. 2A-2B are example schematics of portions of an array of memory cells 200A, such as a NAND memory array. Array of memory cells 200A may be an example of the array of memory cells 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., charge trap and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

FIG. 2D is a block schematic of a portion of an example array of memory cells 260. Array of memory cells 260 can be used as the array of memory cells 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks 250₀ that are within planes 261a, 261b, 261c, and 261d, respectively, and the four blocks 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common data line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

With continued reference to FIGS. 1 and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (VERA or Vera) with an erase pulse while the select gates 210₀ to 210_{M} (SGS transistors) are turned on. Ramping to this high bias erase voltage, and the subsequent recovery from this voltage ramping may take a significant amount of time. Concurrently, the erase operation manager 137 can cause the select gates 212₀ to 212ₘ (FIG. 2A) to be turned off to enable the drains of the select gates 212₀ to 212ₘ to float, which causes the bit lines 204₀ to 204_{M} to also float. Further, the local controller 135 can cause the word lines 202 (FIG. 2A) to be coupled to ground, e.g., zero volts, or cause the word lines 202 to be maintained at a low voltage. This set of voltage levels at the memory array 200A can create an erase potential that causes the memory cells 208₀ to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. In some embodiments, one or more sub-blocks, to include a physical block, of memory cells are erased during the same true erase operation. A block of memory cells can be generally understood to include four or more sub-blocks, wherein each sub-block includes a separate string of memory cells.

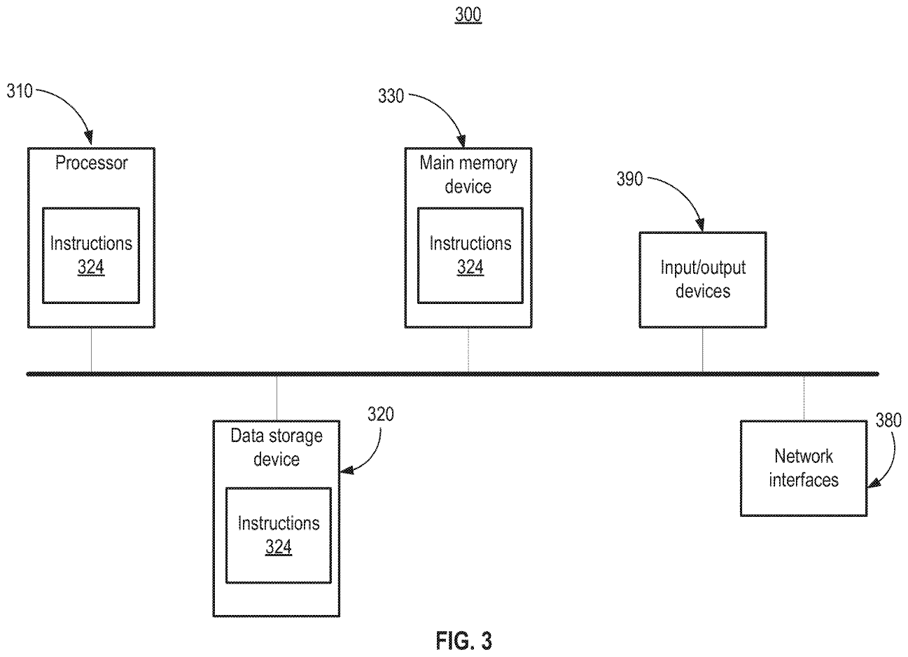

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-10, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 includes a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-10 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-10. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may include one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each include a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

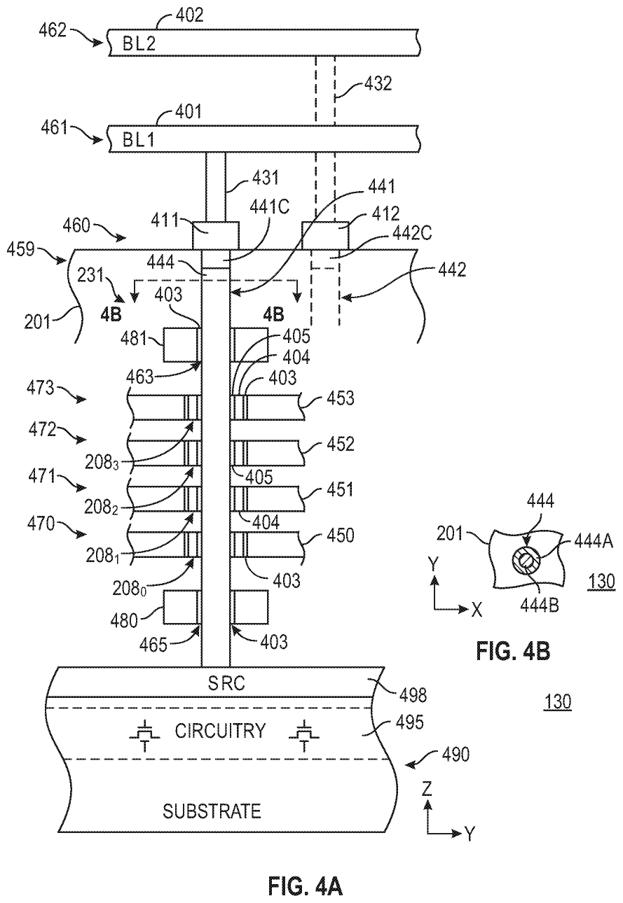

FIG. 4A-FIG. 4B shows a side view (e.g., a cross section with respect to the X-Z directions) of a portion of the three-dimensional structure of memory device 130 including a structure of memory cell string 231 (e.g., a NAND string) having a pillar 441, according to some embodiments described herein. FIG. 4A shows the structure of one memory cell string (e.g., memory cell string 231) of memory device 130. However, other memory cell strings (e.g., NAND strings 206₀-206_{M} in FIG. 2A and NAND strings 206 in FIG. 2B) can have a similar or the same structure as memory cell string 231 shown in FIG. 4A.

Starting from the top of FIG. 4A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIGS. 4A-4B shows directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 4A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 4A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 4A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 4A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 4A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 4A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 4A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 4A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 includes multiple memory cell strings (one of which is shown as memory cell string 231).

As shown in FIG. 4A, pillar (e.g., a vertical pillar) 441 can be a part of memory cell string 231 and can have a length extending in the Z-direction (e.g., extend vertically with respect to substrate 490). Pillar 441 can extend through memory cells 208₀, 208₁, 208₂, and 208₃ of memory cell string 231. Pillar 441 can include (e.g., can be formed from) a conductive material (e.g., conductively doped polysilicon). Each of memory cells 208₀, 208₁, 208₂, and 208₃ can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 4A only shows four memory cells 208₀-208₃, memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 4A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 4A, memory cells 208₀, 208₁, 208₂, and 208₃ of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 4A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 4A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for example, word lines or control gates. Access lines 450, 451, 452, and 453 can include (e.g., can be formed from) a conductive material (or materials). Example materials for access lines 450, 451, 452, and 453 include metal, alloy, doped polysilicon, other conductive materials.

In FIG. 4A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 4A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 4A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory cell. As shown in FIG. 4A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a charge trap (e.g., to store charge) in a memory cell (e.g., a memory cell 208₀, 208₁, 208₂, and 208₃). In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 4A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 4B. FIG. 4B shows a top view (e.g., a cross section with respect to the X-Y plan) of portion 444 of pillar 441 along line 4B-4B of FIG. 4A. As shown in FIG. 4B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

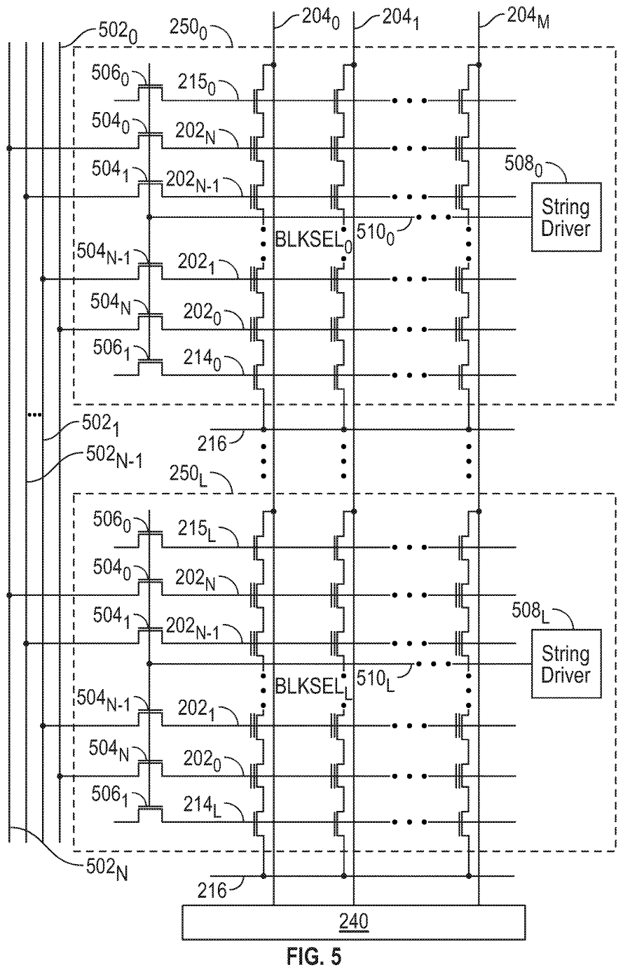

FIG. 5 illustrates an example of a portion of an array of memory cells 208 in a memory device, in accordance with examples as disclosed herein. The array of memory cells includes, and/or is connected to, string drivers 508₀-508_{L}, string transistors 504₀-504_{N}, and select transistors 506₀-506₁. Like numbered elements in FIG. 5 correspond to the description provided above (e.g., memory cells shown in FIG. 5 correspond to the memory cells 208 shown in FIG. 2). FIG. 5 provides additional detail of one example of an array of memory cells 208 in a memory device.

As shown in FIG. 5, the memory cells 208 can be grouped into the blocks 250 (e.g., 250₀-250_{L}). In addition, each of the blocks 250 may include the string transistors 504, the select transistors 506, and a corresponding string driver 508. In one example, string transistors 504 are connected to the memory cells 208 via word lines 202. Select transistors 506 are connected to the select transistors 212 via the select lines 214 and 215. The string drivers 508 can be caused to apply the BLKSEL signal (e.g., a bias voltage) to turn on the string transistors 504 and connect the word lines 202 to global word lines 502₀ to 502_{N}. In addition, the string drivers 508 apply the BLKSEL signal to turn on the select transistors 506 and connect the select lines 214 and 215 to global select lines (not shown). Connecting the word lines 202 to the global word lines 502 and the select lines 214 and 215 to the global select lines can cause some of the corresponding memory cells 208 to turn on or conduct current when receiving particular word line voltages.

The portion of the array of memory cells 208 may include multiple subsets of the word lines 202. In some embodiments, the subsets of the word lines 202 may correspond to different instances of the blocks 250. For example, a first subset of the word lines 202 may correspond to the block 250₀, a second subset of the word lines may correspond to the block 250₁ (not shown but indicated by the ellipsis in FIG. 5), and a third subset of the word lines 202 may correspond to the block 250_{L}.

Each subset of the word lines 202 is coupled to a different group of the memory cells 208. For example, the first subset of the word lines 202 is coupled to the group of memory cells 208 within the block 250₀, the second subset of the word lines 202 is coupled to the group of memory cells 208 within the block 250₁, and the third subset of the word lines 202 is coupled to the group of memory cells 208 within the block 250_{L}.

With combined reference to FIGS. 1 and 5, control logic of the memory device 130 may select a reset read operation scheme to be performed to reset at least some of the memory cells 208 to the transient state. The system controller 115 may select a seamless protocol, which includes switching between the ganged operation and a charge sharing ganged operation (referred to in the present disclosure as “sharing operation”) based on factors of the blocks 250. The terms “control logic,” “local controller” (e.g., the local controller 135), and “system controller” (e.g., the system controller 115) may be used interchangeably in the present disclosure. In some examples, the control logic includes the local controller 135 or the system controller 115. In other example, the control logic includes any combination of the local controller 135, the system controller 115, the page buffer 152, the buffer portion 240, the string drivers 508, the row decoder 108, or the column decoder 111. Operations described in the present disclosure as being performed by the local controller 135 may alternatively be performed by the system controller 115 and vice versa.

In some embodiments, the local controller 135 may control implementation of the seamless protocol based on block addresses and a block decoding scheme. The local controller 135 may determine whether the block address of a current block (e.g., the first subset of word lines 202) and the block address of a next block 250 (e.g., the second subset of word lines 202) are subsequent subsets (e.g., consecutive subsets or neighboring subsets). Block addresses of an example addressing scheme are listed in Table 1.

TABLE 1

| BLOCK | BLOCK ADDRESS | | |
|---|---|---|---|
| BLK 0 | 0 | 0 | 0 |
| BLK 1 | 0 | 0 | 1 |
| BLK 2 | 0 | 1 | 0 |
| BLK 3 | 0 | 1 | 1 |
| BLK 4 | 1 | 0 | 0 |
| BLK 5 | 1 | 0 | 1 |
| BLK 6 | 1 | 1 | 0 |
| BLK 7 | 1 | 1 | 1 |

In the example addressing scheme, the local controller 135 may not be able to distinguish various combinations of the blocks 250 in accordance with the block decoding scheme. For example, the addresses for BLK 0 and BLK 7 may be such that BLK 0 and BLK 7 are indistinguishable to the local controller 135 and are, therefore, not subsequent blocks. Accordingly, BLK 0 and BLK 7 would not be able to be combined for the sharing operation. Using the block addresses listed in Table 1, the following combinations may be possible in accordance with a particular block decoding scheme: BLK 0 and BLK 1; BLK 1 and BLK 2; BLK 2 BLK 3; BLK 3 and BLK 4; BLK 4 and BLK 5; BLK 5 and BLK 6; and BLK 6 and BLK 7.

The local controller 135 may perform the sharing operation for a current block 250 and a next block 250 if they are subsequent. Additionally, the local controller 135 may perform the ganged operation for a current block 250 and a next block 250 if they are not subsequent. Additionally or alternatively, the local controller 135 may perform the ganged operation for a current block 250 and a next block 250 if the next block includes a similar or greater number of good memory cells 208, which is described in detail below.

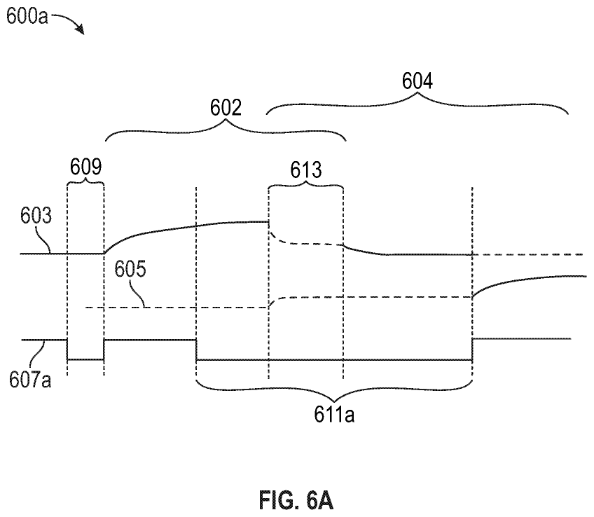

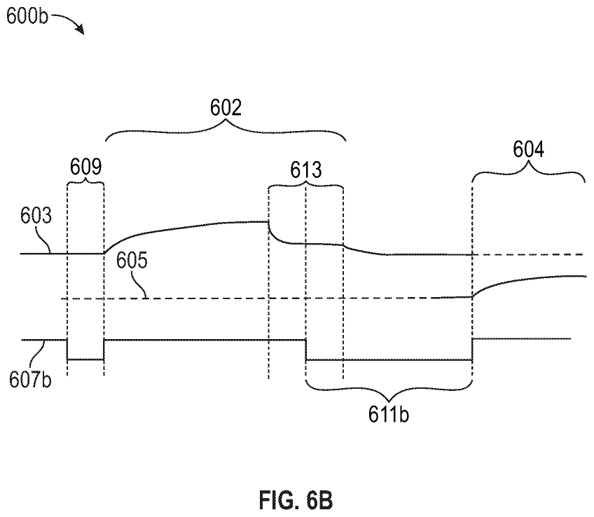

FIGS. 6A and 6B illustrate graphical representations of example sets of waveforms 600a-b corresponding to the seamless protocol, in accordance with examples as disclosed herein. The set of waveforms 600a in FIG. 6A corresponds to the sharing operation of the seamless protocol. The set of waveforms 600b in FIG. 6B corresponds to the ganged operation of the seamless protocol. Both of the sets of waveforms 600a-b include a first word line voltage 603, a second word line voltage 605, and a ready (RDY) signal 607a-b. In FIGS. 6A and 6B, the X or horizontal axis represents time, and the Y or vertical axis represents a voltage level of the various signals.

For the following discussion, the first subset of word lines 202 corresponding to the block 250₀ will be used as an example of the current block 250 and the second subset of word lines 202 corresponding to the block 250₁ and/or the third subset of word lines 202 corresponding to the block 250_{L} will be used as examples of the next block 250.

Single blocks 250 are used as examples for ease of discussion. The embodiments described in the present disclosure may be implemented with ganged block groups rather than single blocks 250. For example, the first subset of word lines 202 may include word lines 202 from a first ganged block group including four blocks 250 and the second subset of word lines 202 may include word lines 202 from a second ganged block group including four different blocks 250.

With combined reference to FIGS. 5, 6A, and 6B, the RDY signal 607a-b indicates whether a reset read operation is to be performed. The first word line voltage 603 indicates a voltage level on a word line of the first subset of word lines 202 during the reset read operations. In addition, the second word line voltage 605 indicates a voltage level on a word line of the second subset of word lines 202 during the reset read operations.

The local controller 135 may determine the timing of the RDY signal 607a-b (e.g., when the RDY signal 607a-b is low or is high) to indicate whether the ganged operation or the sharing operation is to be performed for the next block 250. For example, if the first subset of word lines 202 and the second subset of word lines 202 are subsequent subsets, the local controller 135 may control the timing of the RDY signal 607a in accordance with what is shown in FIG. 6A. Alternatively, if the first subset of word lines 202 and the second subset of word lines 202 are not subsequent subsets, the local controller 135 may control the timing of the RDY signal 607b in accordance with what is shown in FIG. 6B.

The reset read operation for the first subset of word lines 202 may be performed for a first period of time 602. In addition, the reset read operation for the second subset of word lines 202 may be performed for a second period of time 604. As shown in FIGS. 6A and 6B, for both the ganged operation and the sharing operation, the RDY signal 607a-b starts high and then goes low for a period of time 609 (e.g., the local controller 135 transmits a reset read command) to cause the reset read operation to be performed for the first subset of word lines 202.

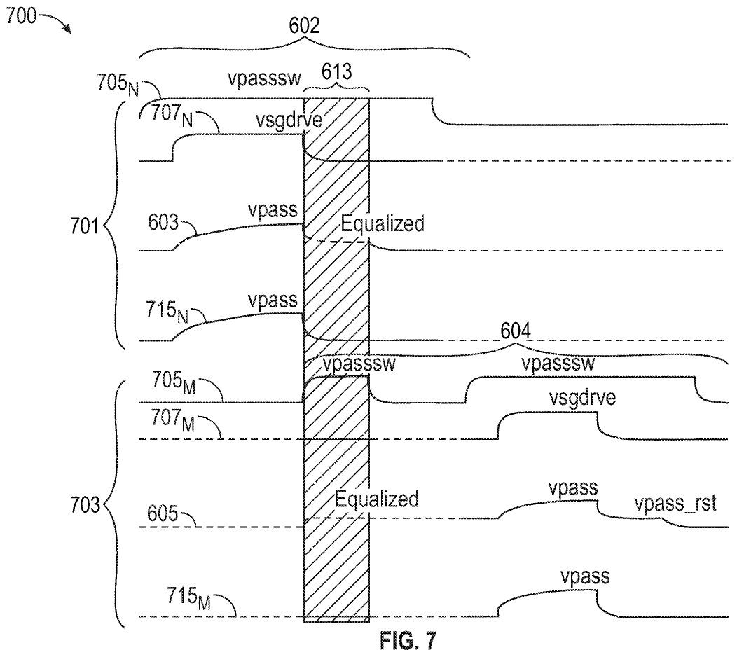

FIG. 7 illustrates a graphical representation 700 of example sets of waveforms 701 and 703 corresponding to the sharing operation, in accordance with examples as disclosed herein. The set of waveforms 701 corresponds to the sharing operation for the first subset of the word lines 202. The set of waveforms 703 corresponds to the sharing operation for the second subset of the word lines 202. The waveforms 701 and 703 include BLKSEL signals 705_{M-N}, SGD signals 707_{M-N}, and select line voltages 715_{M-N}. In FIG. 7, the X or horizontal axis represents time, and the Y or vertical axis represents a voltage level of the various signals.

With combined reference to FIGS. 5, 6A, and 7, at an end of the period of time 609, the local controller 135 causes the string driver 508₀ to provide a first BLKSEL signal 705_{N} via a BLKSEL line 510₀ to turn on the corresponding string transistors 504 for the first period of time 602. In addition, the local controller 135 causes the string driver 508₀ to provide the SGD signal 707_{N} via the BLKSEL line 510₀ to turn on the corresponding select transistors 506 corresponding to the first subset of word lines 202 for the first period of time 602.

After the period of time 609, the first subset of word lines 202 may be biased by the global word lines 502 to cause the voltage level of the first word line voltage 603 to increase from a ground voltage level to a pass-through voltage level (Vpass) (e.g., a level that turns on the corresponding memory cells 208) to perform the reset read operation for the first subset of word lines 202 and reset the corresponding memory cells 208. Additionally, the corresponding select lines 214 and 215 may be biased by the global select lines to cause the select line voltage 715_{N} to increase from the ground voltage level to the Vpass level.

After the period of time 609, the RDY signal 607a goes high to indicate that the array of memory cells 104 are ready for another reset read command. The RDY signal 607a then goes low for a period of time 611a (e.g., the local controller 135 transmits another reset read command) that partially overlaps the first period of time 602. The period of time 611a at least starts prior to a recovery phase 613 of the first period of time 602.

The RDY signal 607a going low for the period of time 611a indicates that the reset read operation is to be performed for the second subset of word lines 202. Because the period of time 611a starts prior to the recovery phase 613 of the first period of time 602 (e.g., the local controller 135 transmits a reset read command prior to the recovery phase 613), the RDY signal 607a indicates that the sharing operation is to be performed for the second subset of word lines 202.

The local controller 135 causes the string driver 508₁ to provide a second BLKSEL signal 705_{M} via a BLKSEL line 510₁ to the second subset of word lines 202 to turn on corresponding string transistors 504 for at least portions of the second period of time 604. In some embodiments, the string driver 508₁ provides the second BLKSEL signal 705_{M} via the BLKSEL line 510₁ at a start of the recovery phase 613. In addition, the local controller 135 may cause the global word lines 502 to float during at least the recovery phase 613. In some embodiments, the local controller 135 may cause the global word lines 502 to float by disconnecting them from a global word line driver (not shown). For example, the local controller 135 may open one or more switches between the global word lines 502 and the global word line driver.

The first subset of word lines 202 may charge the second subset of word lines 202 to a pre-charged voltage level. In some embodiments, the pre-charged voltage level is less than the Vpass level. The first subset of the word lines 202 may share a portion of the charge stored thereon with the second subset of word lines 202 to cause the voltage level of the second word line voltage 605 to increase from the ground voltage level to the pre-charged level. As shown in FIGS. 6A and 7, during the recovery phase 613, the first word line voltage 603 decreases until it is substantially equal to the second word line voltage 605 (e.g., within 500 millivolts (mv) or less of the second word line voltage 605) at the pre-charged voltage level.

In some embodiments, the string driver 508₁ provides the second BLKSEL signal 705_{M} during the recovery phase 613 but not between the recovery phase 613 and the end of the period of time 611a to cause the second subset of word lines 202 to be electrically isolated and float at the pre-charged level.

As shown in FIG. 7, the local controller 135 cause the string driver 508₁ to not provide the SGD signal 707_{M} during the recovery phase 613. For example, the local controller 135 may cause the gates of the corresponding select transistors 506 to be grounded. This may cause the second subset of word lines 202 to float at the pre-charged level.

After the recovery phase 613, the local controller 135 causes the string driver 508₁ to stop providing the second BLKSEL signal 705_{M} to turn off the corresponding string transistors 504. In addition, the local controller 135 causes the string driver 508₁ to stop providing the SGD signal 707_{M} to turn off the select transistors 506. The string transistors 504 and the select transistors 506 corresponding to the second subset of word lines 202 turning off or being off may isolate the second subset of word lines 202 from the first subset of word lines 202 and the global word lines 502. When the string driver 508₀ stops providing the first BLKSEL signal 705_{N} or the SGD signal 707_{N}, the reset read operation for the first subset of word lines 202 may be finished.

At an end of the period of time 611a, the local controller 135 may cause the global word lines 502 to stop floating and be driven. In addition, at the end of the period of time 611a, the local controller 135 causes the string driver 508₁ to provide the second BLKSEL signal 705_{M} to cause the second subset of word lines 202 to connect to the global word lines 502. The second subset of word lines 202 connecting to the global word lines 5012 causes the second word line voltage 605 to increase from the pre-charged level to the Vpass level (e.g., a level that turns on the corresponding memory cells). Additionally, the local controller 135 causes the string driver 508₁ to provide the SGD signal 707_{M} to turn on the select transistors 506. As shown in FIGS. 6A and 7, the second word line voltage 605 floats at the pre-charged level until the end of the period of time 611a. Accordingly, during the sharing operation, the second word line voltage 605 increases from the pre-charged level to the Vpass level rather than from the ground voltage level for the reset read operation for the second subset of word lines 202.

The corresponding select lines 214 and 215 may be biased by the global select lines to cause and the select line voltage 715_{M} to increase from the ground voltage level to the Vpass level. The local controller 135 may repeat the process described above but in relation to the second subset of word lines 202. Accordingly, the charge stored on the first subset of word lines 202 can be shared with the second subset of word lines 202 as part of the sharing operation.

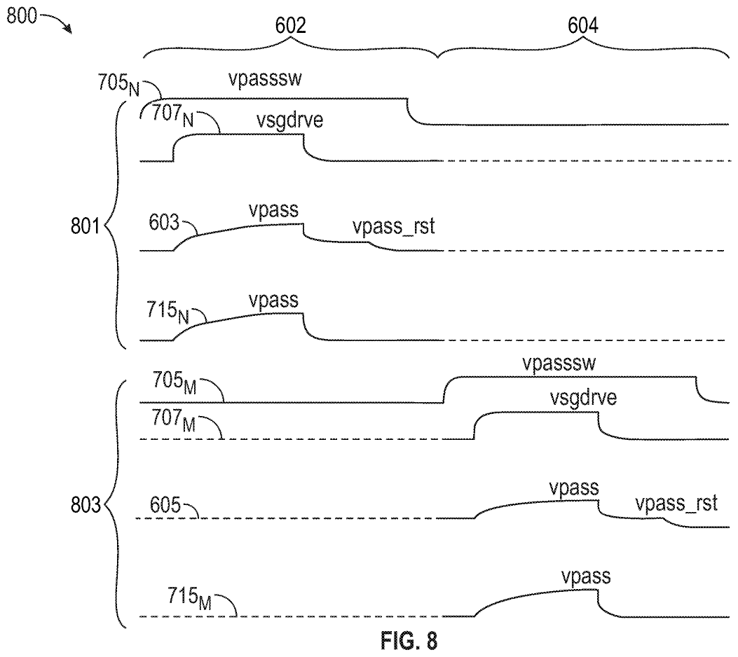

FIG. 8 illustrates a graphical representation 800 of example sets of waveforms 801 and 803 corresponding to the ganged operation, in accordance with examples as disclosed herein. The set of waveforms 801 corresponds to the ganged operation for the first subset of the word lines 202. The set of waveforms 803 corresponds to the ganged operation for the second subset of the word lines 202. In FIG. 8, the X or horizontal axis represents time, and the Y or vertical axis represents a voltage level of the various signals.

With combined referent to FIGS. 5, 6B, and 8, at the end of the period of time 609, the local controller 135 causes the string driver 508₀ to provide the first BLKSEL signal 705_{N} via the BLKSEL line 510₀ to turn on corresponding string transistors 504 for the first period of time 602. In addition, the local controller 135 causes the string driver 508₀ to provide the SGD signal 707_{N} via the BLKSEL line 510₀ to turn on the select transistors 506 corresponding to the first subset of word lines 202 for the first period of time 602.

After the period of time 609, the first subset of word lines 202 may be biased by the global word lines 502 to cause the voltage level of the first word line voltage 603 to increase from the ground voltage level to the pass-through voltage level (Vpass) (e.g., the level that turns on the corresponding memory cells 208) to perform the reset read operation for the first subset of word lines 202 and reset the corresponding memory cells 208. Additionally, the corresponding select lines 214 and 215 may be biased by the global select lines to cause the select line voltage 715_{N} to increase from the ground voltage level to the Vpass level.

After the period of time 609, the RDY signal 607b goes high to indicate that the array of memory cells 104 are ready for another reset read command. The RDY signal 607b then goes low for a period of time 611b (e.g., the local controller 135 transmits another reset read command at a beginning of the period of time 611b) that partially overlaps the first period of time 602. The period of time 611b starts during the recovery phase 613 of the first period of time 602. The RDY signal 607b going low for the period of time 611b that overlaps at least a portion of the recovery phase 613 indicates that the array of memory cells 104 are busy and the shared operation for the second subset of word lines 202 cannot be performed.

Because the period of time 611b starts during the recovery phase 613 (e.g., the reset read command is transmitted after the recovery phase 613 has started), the RDY signal 607b indicates that the ganged operation is to be performed for the second subset of word lines 202. In some embodiments, the RDY signal 607b going low at any time after the start of the recovery phase 613 may indicate that the ganged operation is to be performed for the second subset of word lines 202.

At an end of the period of time 611b, the local controller 135 causes the string driver 508₁ to provide the second BLKSEL signal 705_{M} to the second subset of word lines 202 to turn on corresponding string transistors 504 for the second period of time 604. As shown in FIGS. 6B and 8, the first period of time 602 and the second period of time 604 include independent periods of time. Additionally, the local controller 135 causes the string driver 508₁ to provide the SGD signal 707_{M} to turn on the select transistors 506. The local controller 135 may repeat the process described above but to bias the second word line voltage 605 in relation to the second subset of word lines 202.

Returning to the discussion of the sharing operation and with combined reference to FIGS. 5 and 6A, in some embodiments, the first subset of word lines 202 can share the charge with both the second subset of word lines 202 and the third subset of word lines 202 during the recovery phase 613. In these and other embodiments, the RDY signal 607a going low for the period of time 611a may indicate that the sharing operation is to be performed for both the second subset of word lines 202 and the third subset of word lines 202. Accordingly, the second subset of word lines 202 can charge share with the third subset of word lines 202.

In some embodiments, the local controller 135 may determine if the first subset of word lines 202 and the second subset of word lines 202 are subsequent subsets based on whether the second subset of word lines 202 corresponds to a similar or a greater number of good memory cells 208 or blocks 250 compared to the first subset of word lines 202. If the second subset of word lines 202 corresponds to a similar or a greater number of good memory cells 208 or blocks 250 compared to the first subset of word lines 202, the first subset of word lines 202 and the second subset of word lines 202 may be subsequent subsets. If the second subset of word lines corresponds to a smaller number of good memory cells 208 or blocks 250 compared to the first subset of word lines 202, the first subset of word lines 202 and the second subset of word lines 202 may not be subsequent subsets.

The system controller 115 and/or the local controller 135 may identify memory cells 208 or blocks 250 that are not functioning or not functioning as desired and store that information in a cell map or a block map. For example, the system controller 115 may perform a verification process on the memory cells 208 or the blocks 250 during the power up to identify functional memory cells 208 or functional blocks 250 (e.g., memory cells 208 or blocks 250 that are operating as expected). The system controller 115 may identify an entire block 250 as not functioning or not functioning as desired if one or more memory cells 208 within the block is defective, not functioning, or not functioning as expected.

During the reset read operation, the local controller 135 may identify a number of functional blocks 250) corresponding to the first subset of word lines 202 (e.g., a number of functional memory cells 208 of a first group of memory cells 208). In addition, the local controller 135 may identify a number of functional blocks 250 corresponding to the second subset of word lines 202 (e.g., a number of functional memory cells 208 of a second group of memory cells 208). For example, the local controller 135 may access the block map to identify the functional blocks 250 of the different groups of blocks 250.

During the reset read operation, the local controller 135 may identify a number of functional memory cells corresponding to the first subset of word lines 202 (e.g., a number of functional memory cells 208 of a first group of memory cells 208). In addition, the local controller 135 may identify a number of functional memory cells 208 corresponding to the second subset of word lines 202 (e.g., a number of functional memory cells 208 of a second group of memory cells 208). For example, the local controller 135 may access the cell map to identify the functional memory cells 208 of the different groups of memory cells 208.

The local controller 135 may compare the number of functional blocks 250 of the first group of memory cells 208 to the number of functional blocks 250 of the second group of memory cells 208. If the numbers are equal or the number of functional blocks 250 of the second group of memory cells 208 is greater, the local controller 135 may identify the first subset of word lines 202 and the second subset of word lines as subsequent subsets.

The local controller 135 may compare the number of functional memory cells 208 of the first group of memory cells 208 to the number of functional memory cells 208 of the second group of memory cells 208. If the numbers are equal or the number of functional memory cells 208 of the second group of memory cells 208 is greater, the local controller 135 may identify the first subset of word lines 202 and the second subset of word lines as subsequent subsets.

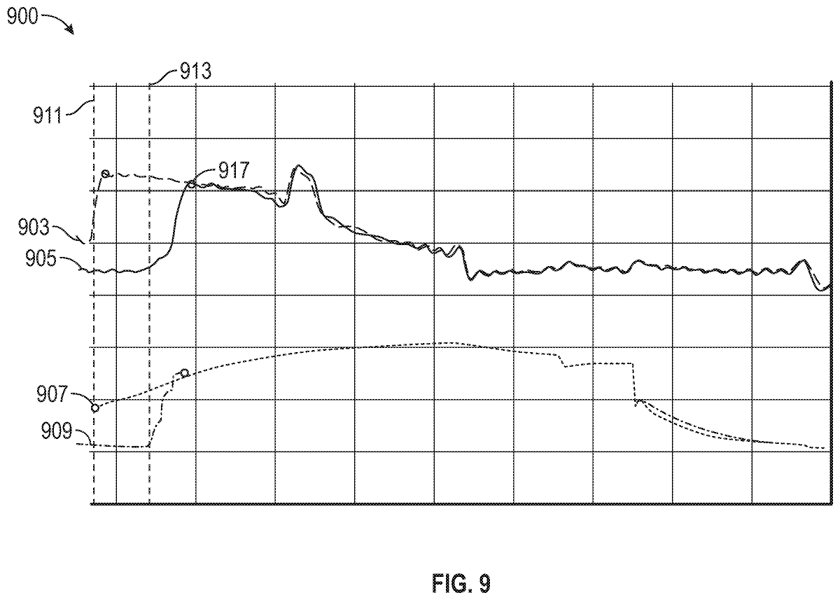

FIG. 9 illustrates a graphical representation 900 of operating currents 903 and 905 of a memory device and word lines voltages 907 and 909 captured as part of a simulation of the ganged operation and a simulation of the sharing operation, in accordance with examples as disclosed herein. In FIG. 9, the X or horizontal axis represents time, and the Y or vertical axis represents a voltage level or a current level of the various signals. In an embodiment, a scale or a step size of the Y axis includes five microseconds (μs). In an embodiment, a scale or a step size of the X axis includes fifty mv for the voltage level of the various signals.

The simulation was performed using an eight block ganged group of blocks. The operating current 905 and the word line voltage 909 correspond to the sharing operation. The operating current 903 and the word line voltage 907 correspond to the ganged operation.

As shown in FIG. 9, a peak 917 of the operating current 905 for the sharing operation is reduced by, for example, nineteen percent compared to a peak 915 of the operating current 903 for the ganged operation. The peaks 915 and 917 occurred during a ramp up phase for the reset read operations. The reduction in the peak 917 of the operating current 905 can reduce an amount of power consumed by a memory device during the sharing operation compared to the ganged operation.

A ramp time for the word line voltage 907 started at a first point in time 911 and a ramp time of the word line voltage 909 started at a second point in time 913. As shown in FIG. 9, the first point in time 911 is roughly 3.6 μs earlier than the second point in time 913. Accordingly, the ramp time for the word line voltage 909 is roughly 3.6 μs shorter than the ramp time for the word line voltage 907. The reduction in the ramp time for the word line voltage 909 can reduce an amount of time taken to perform the reset read operation and/or reduce the amount of power consumed by a memory device during the sharing operation compared to the ganged operation.

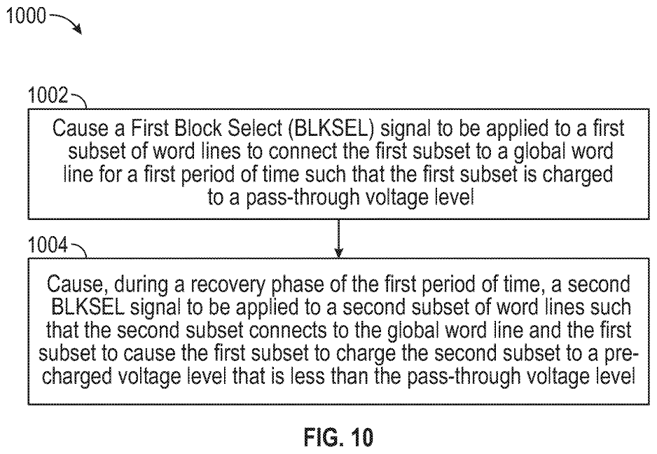

FIG. 10 illustrates a flowchart showing a method 1000 that supports techniques for performing low power ganged reset read in accordance with examples as disclosed herein. At least some of the blocks in method 1000 can be performed by control logic (e.g., the local controller 135 or the system controller 115 of FIG. 1) during a reset read operation. At block 1002, the control logic causes a first BLKSEL signal to be applied to a first subset of word lines (e.g., the word lines 202 of the Block 250₀) to connect the first subset to a global word line (e.g., global word lines 502) for a first period of time such that the first subset is charged to a pass-through voltage level. For example, the local controller 135 or the system controller 115 may cause the string driver 508₀ to apply the BLKSEL signal to turn on the corresponding string transistors 504 and connect the corresponding word lines 202 to the global word lines 502 to charge the corresponding subset of the memory cells 208 for the first period of time.

In block 1004, the control logic causes, during a recovery phase of the first period of time, a second BLKSEL signal to be applied to a second subset of word lines (e.g., the word lines 202 of the Block 250_{L}) such that the second subset connects to the global word lines 502 and the first subset to cause the first subset to charge the second subset to a pre-charged voltage level that is less than the pass-through voltage level. For example, the local controller 135 or the system controller 115 may cause the string driver 508₁ to apply the BLKSEL signal to turn on the corresponding string transistors 504 and connect the corresponding word lines 202 to the global word lines 502 to pre-charge the corresponding subset of the memory cells 208.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and include a three terminal device including a source, drain, and gate. The terminals may be connected to other electronic elements through conductive materials, e.g., metals. The source and drain may be conductive and may include a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
a global word line;
a plurality of word lines comprising:
a first subset coupled to a first group of memory cells; and
a second subset coupled to a second group of memory cells; and
control logic configured to:
cause a first block select (BLKSEL) signal to be applied to the first subset to connect the first subset to the global word line for a first period of time such that the first subset is charged to a pass-through voltage level; and
cause, during a recovery phase of the first period of time, a second BLKSEL signal to be applied to the second subset such that the second subset connects to the global word line and the first subset to cause the first subset to charge the second subset to a pre-charged voltage level that is less than the pass-through voltage level.

2. The memory device of claim 1, wherein the control logic is configured to cause the second BLKSEL signal to be applied to the second subset for a second period of time such that the second subset is charged from the pre-charged voltage level to the pass-through voltage level.

3. The memory device of claim 2, wherein:
the plurality of word lines comprises a third subset coupled to a third group of memory cells; and
the control logic is configured to:
determine the second subset and the third subset are subsequent subsets in accordance with a block decoding scheme of block addresses; and
cause, during a recovery phase of the second period of time, a third BLKSEL signal to be applied to the third subset such that the third subset connects to the global word line and the second subset to cause the second subset to charge the third subset to the pre-charged voltage level.

4. The memory device of claim 3, wherein the control logic is configured to cause the third BLKSEL signal to be applied to the third subset to connect the third subset to the global word line for a third period of time such that the third subset is charged from the pre-charged voltage level to the pass-through voltage level.

5. The memory device of claim 2, wherein:
the plurality of word lines comprises a third subset coupled to a third group of memory cells; and
the control logic is configured to:
determine the second subset and the third subset are not subsequent subsets in accordance with a block decoding scheme of block addresses; and
cause a third BLKSEL signal to be applied to the third subset to connect the third subset to the global word line for a third period of time such that the third subset is charged to the pass-through voltage level.

6. The memory device of claim 5, wherein the control logic is configured to transmit a reset read command after a recovery phase of the second period of time to cause the third BLKSEL signal to be applied to the third subset after the recovery phase of the second period of time.

7. The memory device of claim 1, wherein:
the first subset comprises one or more word lines of the plurality of word lines; and
the second subset comprises one or more word lines of the plurality of word lines that is different than the one or more word lines of the first subset.

8. The memory device of claim 1, wherein the first subset charges the second subset from a ground voltage level to the pre-charged voltage level during the recovery phase of the first period of time.

9. The memory device of claim 1, wherein the control logic is configured to cause the second BLKSEL signal to stop being applied to the second subset after the recovery phase of the first period of time to cause the second subset to be electrically isolated and float at the pre-charged voltage level.

10. The memory device of claim 1, wherein the first subset and the second subset comprise consecutive subsets of the plurality of word lines in accordance with a block decoding scheme of block addresses.

11. The memory device of claim 1, wherein:
the plurality of word lines comprises a third subset coupled to a third group of memory cells; and
the control logic is configured to:
cause, during the recovery phase of the first period of time, a third BLKSEL signal to be applied to the third subset such that the third subset connects to the global word line and the first subset to cause the first subset to charge the third subset to the pre-charged voltage level that is less than the pass-through voltage level.

12. The memory device of claim 1, wherein the control logic is configured to:
identify a number of functional blocks of the first group of memory cells and a number of functional blocks of the second group of memory cells;
compare the number of functional blocks of the first group of memory cells to the number of functional blocks of the second group of memory cells; and
cause, during the recovery phase of the first period of time, the second BLKSEL signal to be applied to the second subset in accordance with a result of the comparison.

13. A method comprising:
causing a first block select (BLKSEL) signal to be applied to a first subset of word lines to connect the first subset to a global word line for a first period of time such that the first subset is charged to a pass-through voltage level; and
causing, during a recovery phase of the first period of time, a second BLKSEL signal to be applied to a second subset of word lines such that the second subset connects to the global word line and the first subset to cause the first subset to charge the second subset to a pre-charged voltage level that is less than the pass-through voltage level.

14. The method of claim 13, wherein the second BLKSEL signal is applied to the second subset for a second period of time such that the second subset is charged from the pre-charged voltage level to the pass-through voltage level.

15. The method of claim 14 further comprising:
determining the second subset and a third subset are subsequent subsets in accordance with a block decoding scheme of block addresses; and
causing, during a recovery phase of the second period of time, a third BLKSEL signal to be applied to the third subset such that the third subset connects to the global word line and the second subset to cause the second subset to charge the third subset to the pre-charged voltage level.

16. The method of claim 14 further comprising:
determining the second subset and a third subset are not subsequent subsets in accordance with a block decoding scheme of block addresses; and
causing a third BLKSEL signal to be applied to the third subset to connect the third subset to the global word line for a third period of time such that the third subset is charged to the pass-through voltage level.

17. The method of claim 16 further comprising transmitting a reset read command after a recovery phase of the second period of time to cause the third BLKSEL signal to be applied to the third subset after the recovery phase of the second period of time.

18. The method of claim 13 further comprising causing the second BLKSEL signal to stop being applied to the second subset after the recovery phase of the first period of time to cause the second subset to be electrically isolated and float at the pre-charged voltage level.

19. The method of claim 13 further comprising:
causing, during the recovery phase of the first period of time, a third BLKSEL signal to be applied to a third subset such that the third subset connects to the global word line and the first subset to cause the first subset to charge the third subset to the pre-charged voltage level that is less than the pass-through voltage level.

20. The method of claim 13 further comprising:
identifying a number of functional blocks of a first group of memory cells corresponding to the first subset and a number of functional blocks of a second group of memory cells corresponding to the second subset;
comparing the number of functional blocks of the first group of memory cells to the number of functional blocks of the second group of memory cells; and
causing, during the recovery phase of the first period of time, the second BLKSEL signal to be applied to the second subset in accordance with a result of the comparison.
